(19) United States
(12) Patent Application Publication
(10) Pub. No.: US 2006/0280278 A1
(43) Pub. Date: Dec. 14, 2006

(54) Frequency divider circuit with a feedback shift register

(76) Inventors: Stefan Schabel, Syrgenstein (DE); Holger Schulz, Erbach (DE)

Correspondence Address: MCGRATH, GEISSLER, OLDS & RICHARDSON, PLLC, P.O. BOX 1364, FAIRFAX, VA, 22038-1364, US

(21) Appl. No.: 11/450,399

(22) Filed: Jun. 12, 2006

(30) Foreign Application Priority Data
Jun. 10, 2005 (DE) DE10 2005 028 119

(51) Int. Cl. H03K 21/00

(52) U.S. Cl. 377/47

(57) ABSTRACT

A frequency divider circuit is disclosed, which has a chain of flip-flops that are connected by a feedback path to a feedback shift register, and has a start circuit that produces a defined initial state of the shift register when the frequency divider circuit is switched on. The start circuit blocks the feedback path for a predetermined length of time following a power up of the frequency divider circuit.

This nonprovisional application claims priority under 35 U.S.C. § 119(a) on German Patent Application No. DE 10 2005 028 119, which was filed in Germany on Jun. 10, 2005, and which is herein incorporated by reference.

### BACKGROUND OF THE INVENTION

1. Field of the Invention

The present invention relates to a frequency divider circuit having a chain of flip-flops that are connected by a feedback path to a feedback shift register, and having a start circuit that produces a defined initial state of the shift register when the frequency divider circuit is switched on.

2. Description of the Background Art

A frequency divider circuit is disclosed in U.S. Pat. No. 6,459,310 B1, which proposes standard CMOS elements for implementing a flip-flop and represents such CMOS elements as especially advantageous. In this circuit, a defined initial state is produced at switch-on (power up) by a reset signal, which is supplied to each of the flip-flops synchronously. As a result, the prior art circuit requires, in addition to a start circuit which provides the reset signal at power up, a line layout with a plurality of reset lines. These lines, which must be provided in addition to clock signal lines and data signal lines of the shift register, increase the circuit's space requirements.

### SUMMARY OF THE INVENTION

It is therefore an object of the present invention to provide a frequency divider circuit with a reduced space requirement.

This object is attained in a frequency divider circuit in that the start circuit blocks the feedback path for a predetermined length of time following a power up of the frequency divider circuit.

An undesirable waveform is thus not fed back into the shift register on account of the blocked (i.e., interrupted) feedback. The interrupted feedback allows the establishment of a defined reset of the shift register at power up with a reduced space requirement. For example, with interrupted feedback, no undesirable states of individual flip-flops are fed back into the first flip-flop, which can instead be supplied with defined states, for example logic zeroes. The defined states are shifted through the shift register by sequential clocking until all flip-flops are filled with the defined states, representing a defined, initial state of the shift register. Thus, the data lines of the shift register are used for the reset, in a certain sense, so that separate reset lines are not required. This results in the further critical advantage that the individual flip-flops need not have separate reset functions for a synchronous reset of all flip-flops, since they are, so to speak, sequentially driven into a defined state through their data inputs, which are present in any case. Simple flip-flops can thus be used, resulting in a further reduced space requirement for the frequency divider circuit.

With regard to embodiments of the frequency divider circuit, the predetermined length of time can be greater than or equal to a number of periods of a clock signal which is applied synchronously to each flip-flop of the shift register.

Thu, all flip-flops can be in a defined state before the feedback path is closed. In this way, an undesirable feedback of undesirable states, and the associated undesirable waveforms, are avoided in an efficacious manner.

The start circuit can have a pair of complementary MOS transistors with their gate terminals connected to one another, and also has an RC element, for conductivity paths of the MOS transistors to be connected through an ohmic resistance of the RC element and to be connected in series between a supply voltage and a reference voltage, and for a capacitor of the RC element to be connected in parallel to a conductivity path of one of the MOS transistors.

This embodiment represents a simple-to-realize implementation of a start circuit with the desired characteristics. Generally speaking, feedback shift registers which are used as frequency dividers can exhibit undesirable waveforms, for example interfering rising and falling edges within the repeating periods. The start circuit with the aforesaid features prevents this undesirable effect. Thus, for example, after a trigger event such as a power up signal, sufficient zeros are written into the shift register, so that all cells of the shift register are guaranteed to be at zero. Then a defined start of the synchronous frequency divider is guaranteed, with undesirable waveforms reliably being avoided by this means.

The flip-flops can also have emitter-coupled bipolar transistors as circuit elements (ECL technology, ECL=emitter-coupled logic).

Typically, individual flip-flops are implemented in CMOS technology, and this is also the case in U.S. Pat. No. 6,459,310. As is well known, CMOS technology is distinguished by a lower current demand in comparison to bipolar technology as a result of the voltage control of the MOS transistors involved. In static operation, the current consumption of CMOS circuits is thus relatively low. By contrast, bipolar transistors require certain control currents even in static operation. In actual circuit processes, however, which is to say in dynamic operation, CMOS circuits also consume current, since the gate capacitances of the MOS transistors are charged or discharged when they are driven. This current consumption rises with the number of charging or discharging processes needed, and thus increases with frequency. Moreover, the current consumption depends on the structure width of the CMOS components, and decreases with decreasing structure width. The frequency dependence of the current consumption of CMOS circuits is disadvantageous, particularly at the relatively high frequencies of a clock signal to be divided. In this regard, relatively high frequencies are considered to be frequencies above approximately 200 MHz, in particular above approximately 400 MHz, such as are used, for example, in voltage-controlled oscillators in GPS receivers or in generating standard frequencies for a GPS receiver from a reference frequency.

The fact that the use of bipolar transistors offers advantages in this context is surprising at first, since bipolar transistors represent current-controlled components which exhibit a certain current consumption even in static operation. At low frequencies, this current consumption is, in any case, higher than the current consumption of CMOS circuits. ECL circuits have the smallest gate propagation delay of all logic families and have only small collector-base junction capacitances. They are switched with relatively small signal amplitudes of a few hundred mV. In this way, the unavoidable circuit capacitances are rapidly charged or discharged. The low output resistance of the emitter follower also favors short switching times. However, the high switching speed of ECL circuits is generally associated with high power dissipation.

Nonetheless, one great advantage of emitter-coupled bipolar transistors is that their current demand is approximately frequency-independent. It has been shown that, at a certain cross-over frequency which is less than 400 MHz in any case, the frequency-independent current demand of CMOS latches exceeds the current demand of emitter-coupled bipolar transistors, which is approximately independent of the frequency of the clock signal. The frequency of 400 MHz should not be considered a sharp, generally valid number that applies to all CMOS technologies and bipolar technologies, since the current consumption of CMOS circuits also depends on their structure width and decreases with decreasing structure width. With decreasing structure width, the cross-over frequency above which bipolar transistors have more favorable characteristics can thus also be higher. Nonetheless, the figure of 400 MHz is valid for CMOS structure widths of 0.35 micrometers in particular.

Further, the feedback path can have a first feedback branch, a second feedback branch, and an AND gate, wherein the AND gate connects the first and second feedback branches to a data input of a first flip-flop of the shift register, and wherein the first feedback branch is supplied by a next-to-last flip-flop of the shift register and the second feedback branch is supplied by a last flip-flop of the shift register.

This embodiment with a synchronously clocked shift register is distinguished by an advantageous low sensitivity to production tolerances and temperature effects. Moreover, it results in a duty cycle of the divided signal that approaches the ideal value of 50% with increasing frequency difference between the clock signal and the divided signal, in other words with increasing division ratio. At a division ratio of 13 (the frequency of the clock signal is 13 times the frequency of the divided signal), a duty cycle of 46% is already produced.

It is also preferred that outputs of the last and next-to-last flip-flops of the shift register are connected through an OR gate and that an output of the OR gate constitutes an output of the frequency divider circuit.

By means of this embodiment, a duty cycle of 50% is achieved in the output signal of the frequency divider circuit.

A preferred application of these embodiments results in particular at a clock signal frequency (cutoff frequency) that is greater than 200 MHz, and in particular is greater than 400 MHz.

The frequency divider circuits presented can be used to generate a GPS standard frequency from an internal reference frequency of a communication device, for example.

By means of this embodiment, it is possible to eliminate a separate reference frequency generator (e.g., a quartz crystal) for the GPS standard frequency when, for example, a GPS receiver is integrated in a mobile communication device, e.g. a mobile telephone, that already has an internal reference frequency generator.

It is also preferred for the GPS standard frequency to be generated by a chain of frequency multipliers and frequency dividers and a phase-locked loop.

As explained below with regard to FIG. 7, it is also possible in this way to generate odd-numbered ratios between an internal reference frequency of a mobile communication device and the desired GPS frequency in a manner that is stable while also saving both space and current.

It is also preferred for frequency dividers of the chain which divide a frequency that is greater than a cutoff frequency to be implemented in bipolar technology, while frequency dividers of the chain which divide a frequency lower than the cutoff frequency are implemented in CMOS technology.

By this means, the total current demand of the chain is minimized. This is especially advantageous for mobile applications in which current consumption is a critical parameter because of limited rechargeable battery capacity.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 illustrates a first example embodiment of a frequency divider circuit according to the invention;

FIG. 2 shows time-correlated curves of a variety of signals that occur in the frequency divider circuit from FIG. 1;

FIG. 3 illustrates an embodiment of a start circuit;

FIG. 4 shows a single latch constructed in bipolar ECL technology;

FIG. 5 shows a master/slave flip-flop having two latches as per FIG. 4;

FIG. 6 is a qualitative representation of current consumption of an inventive frequency divider over frequency in comparison to a known frequency divider operating with standard CMOS cells; and

FIG. 7 illustrates a frequency conversion circuit that converts a typical internal reference frequency of a mobile telephone to a conventional standard frequency for a GPS application.

### DETAILED DESCRIPTION

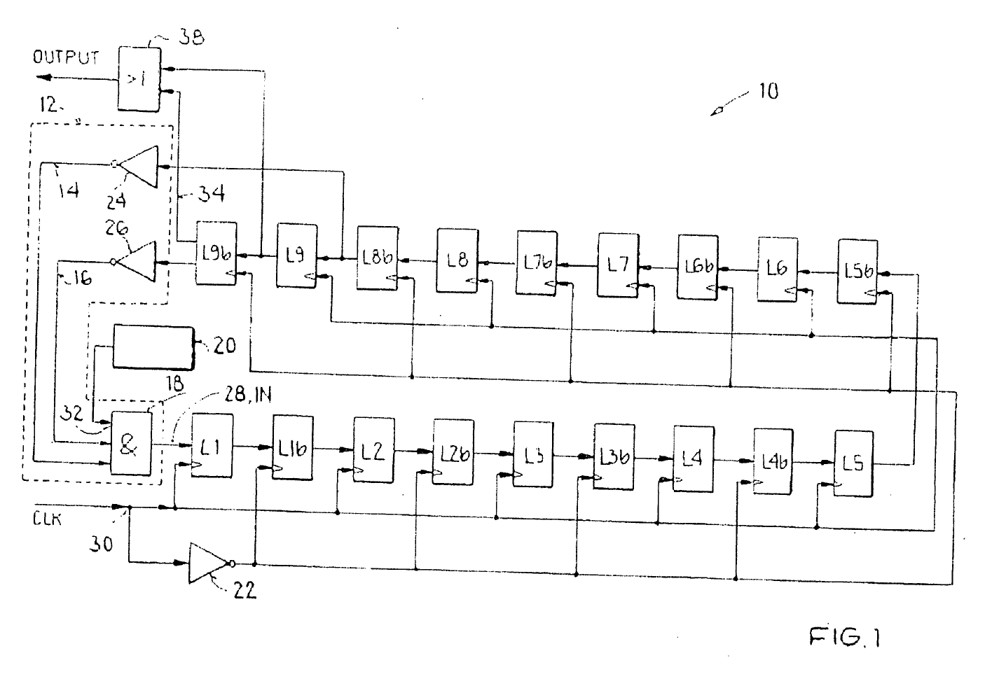

Specifically, FIG. 1 shows a basic structure of a synchronous (1:17) frequency divider circuit 10 with features of the invention. The frequency divider circuit 10 includes a feedback shift register with i_max=9 MSD flip-flops, each having two latches Li, Lib with i=1, 2, . . . i_max=9, which are connected to a feedback path 12 having a first feedback branch 14, a second feedback branch 16 and an AND gate 18, and also to a start circuit 20, to form a feedback shift register. Each pair of latches Li, Lib with the same index i constitutes, together with the inverter 22, an MSD flip-flop. A preferred embodiment of such an MSD flip-flop whose individual latches are implemented in bipolar circuit technology, is explained further below.

Outputs of the sixteenth latch (L8b) and of the eighteenth latch (L9b) are fed back inverted to the input of the first latch (L1) through the feedback branches 14 and 16. To this end, each of the two feedback branches 14, 16 has an inverter 24, 26.

Each signal arrow in FIG. 1 represents lines for one differential signal each. The signal arrow 28, for example, represents lines for a differential input signal of values Wd, Wdn, as will be explained further below.

Accordingly, the additional signal arrows represent lines that transfer this differential input signal to a following latch Lj+1, Lj+1b with a delay that depends on the number of preceding latches Lj, Ljb.

A differential clock signal CLK is applied at an input 30 of the frequency divider 10. The first feedback branch 14 is connected to the signal path ahead of the next-to-last latch Li_max-1 (between L8b and L9 in FIG. 1), where it obtains a signal. This signal, which represents the input signal of the last MSD flip-flop, is transferred in inverted form to the AND gate 18.

Moreover, in a similar fashion the second feedback branch 16 transfers the inverted output signal of the last MSD flip-flop from the latches L9, L9b to the AND gate 18. The AND gate 18 also has an input 32 for the start circuit 20, which is described in detail further below. For understanding the function of the frequency divider 10, it is sufficient for now that the start circuit 20 can block the feedback path 12 in a predefined manner in conjunction with the AND gate 18 in order to produce a defined, initial state of the shift register.

The AND gate 18 only supplies a logic one as input signal IN to the first latch L1 if all inputs of the AND gate 18 are at one. As long as the start circuit 20 supplies a logic zero, a logic zero is present at the input of the first latch L1. The logic zero is then shifted through all latches Li, Lib at the clocking of the clock signal so that the shift register is completely filled with zeros in a sequential manner for an initial state.

At the first rising edge of the clock signal, L1 goes to zero, at the first falling edge L1b goes to zero, a the second rising edge, L2 goes to zero, at the second falling edge L2b goes to zero, and so on, until the i_max=ninth falling edge L9b goes to zero and the shift register is entirely filled with zeros.

Because of the inverters 24, 26 in the feedback branches 14, 16, two logic one values and the signal of the start circuit 20 are then present at the AND gate 18. If the start circuit 20 then goes to one, the AND gate 18 switches its output signal IN from a logic zero to a logic one. This logic one is likewise shifted through the shift register in successively delayed fashion until the one appears at the output of L8b. This one is then inverted in the first feedback branch 14, which finally switches the AND gate 18 over, so that the AND gate again feeds logic zeros into the shift register. After another falling edge in the clock signal, the second feedback branch 16 also supplies an inverted one, which is to say a zero, to the AND gate 18.

The zeros output by the AND gate 18 are shifted through the shift register in successive fashion until both the first feedback branch 14 and the second feedback branch 16 again supply a one to the AND gate 18.

As the process continues further, nine zeros alternating with eight ones are generated at the input of each latch Li, Lib for 17 full periods of the clock signal. As this occurs, the latches L1 through L9 are triggered by the positive edge of the input signal IN, while the latches L1b through L9b are triggered by the inverter 22 with the negative edge of the input signal IN. As a result, nine zeros appear at the input of L1. After that, ones are present at this input for eight clocks in a row. This period or waveform (00000000011111111) always occurs when the shift register has been placed in the defined initial state with the start circuit 20. The frequency divider circuit 10 divides the frequency of the clock signal CLK by a factor of 17, thus generating an output signal with a duty cycle of 8/17=46.7%, which can be obtained at the output of the latch L9b. The signal defined in this manner thus has 17 times the period duration, and hence 1/17 the frequency, of the clock signal CLK. In this way, any odd-numbered division ratio can be obtained through the definition of the number 2*i_max of latches Li, Lib.

As described thus far, the signal with the divided frequency still has a duty cycle differing from the ideal value of 50%, since in the case of the 1/17 divider described, a high level (level=1) results for 8/17 of a period, and a low level (level=0) results for 9/17 of a period.

The deviation here is proportional to a factor of 1/n, where n is the number of latches Li, Lib reduced by one, which is to say n=2*i_max−1.

At the output of the optional OR gate 38, in contrast, an output signal OUTPUT can be obtained with the divided frequency with a duty cycle of 50%.

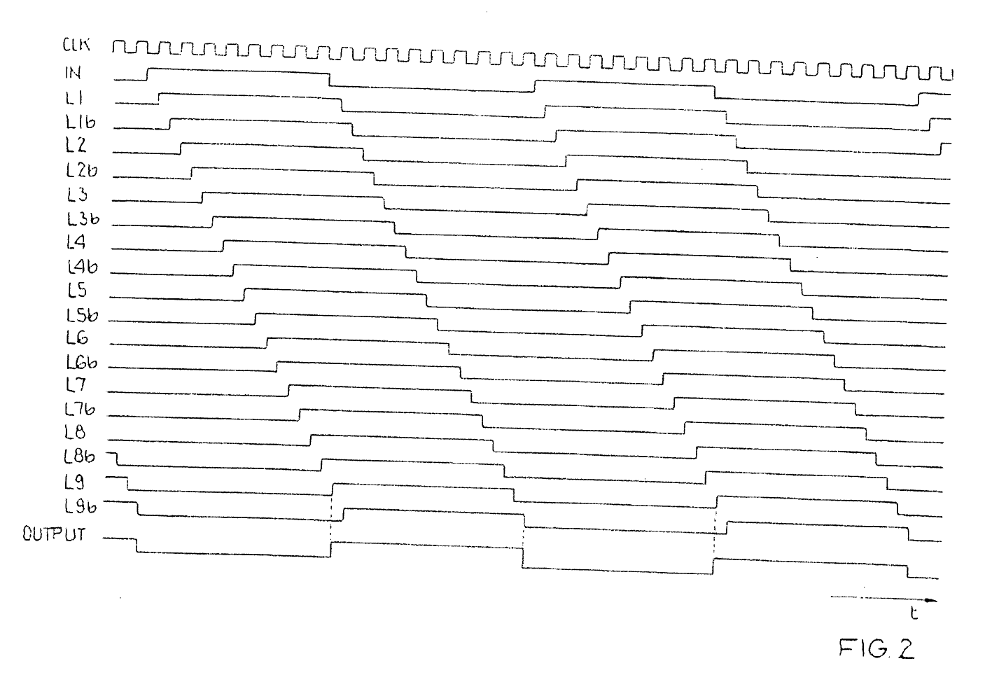

FIG. 2 shows time-correlated curves of the aforementioned signals, CLK, IN, OUTPUT, and of the output signals of the latches Li, Lib following a defined start of the shift register after a power up.

FIG. 3 shows an embodiment of a start circuit 20 which has a pair of complementary MOS transistors 40, 42 with their gate terminals connected to one another, and also has an RC element 44. Here, conductivity paths of the MOS transistors 40, 42 are connected through an ohmic resistance R of the RC element 44 and are connected in series between a supply voltage VCC and a reference voltage gnd. A capacitor C of the RC element 44 is connected in parallel to a conductivity path of one of the MOS transistors 40, 42. In this way, the start circuit 20 is activated such that a trigger signal at an input NPU (NPU=Not Power Up) is switched from one (Power Down) to zero (Power Up). The NMOS transistor 40 is inhibited in this moment, and the PMOS transistor 42 is switched on. In this way, the capacitor C is charged through the resistance R. The time constant R*C of this RC element 44 determines the delayed forwarding of the trigger signal at an output OUT of the start circuit 20. The delayed power up signal PU can be tapped at the output of an optional CMOS buffer B.

For use as a start circuit 20 in a bipolar, synchronous frequency divider 10 with latches implemented in ECL technology, the CMOS signal PU must be converted into an ECL signal, which is accomplished by the block 46 (MOS to ECL). The output signal OUT of the start circuit 20 is now provided along with the feedback signals to the feedback branches 14, 16 of the shift register at the AND gate 18 from FIG. 1. This has the result that, after activation of the frequency divider 10 by a trigger signal at the input NPU of the start circuit 20, the shift register is first filled with zeros. Not until the output signal at the output OUT of the start circuit 20 changes from “low” to “high” does the feedback of the shift register become active. The frequency divider 10 from FIG. 1 starts in a defined state when the time constant of the start circuit 20 is large enough (for the divider in FIG. 1, this is larger than 9 clock cycles of the clock signal CLK) to fill the entire shift register with zeros.

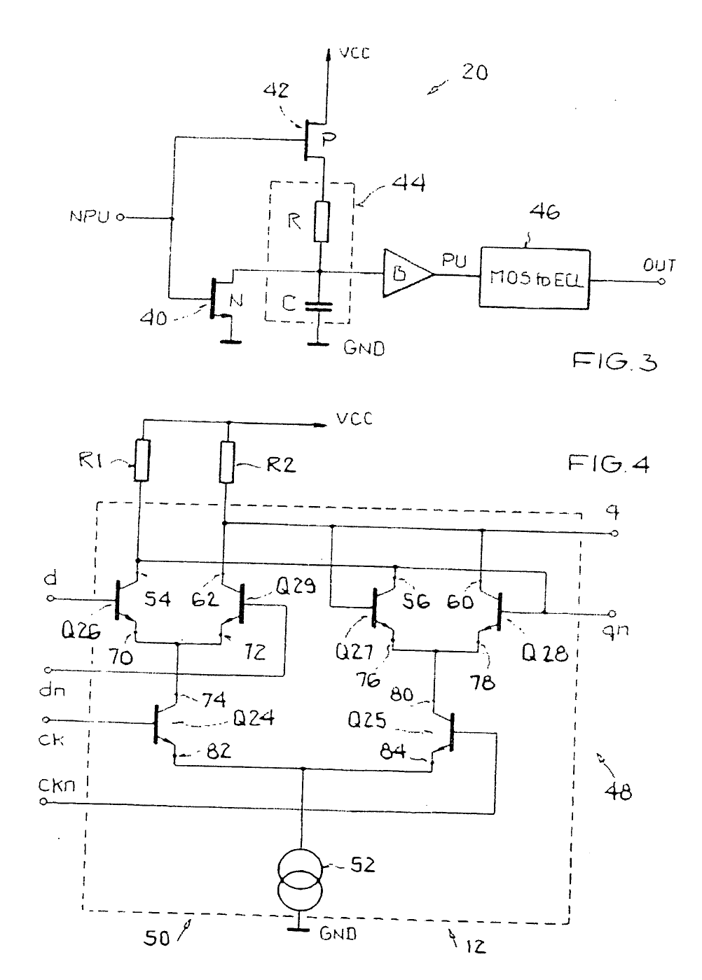

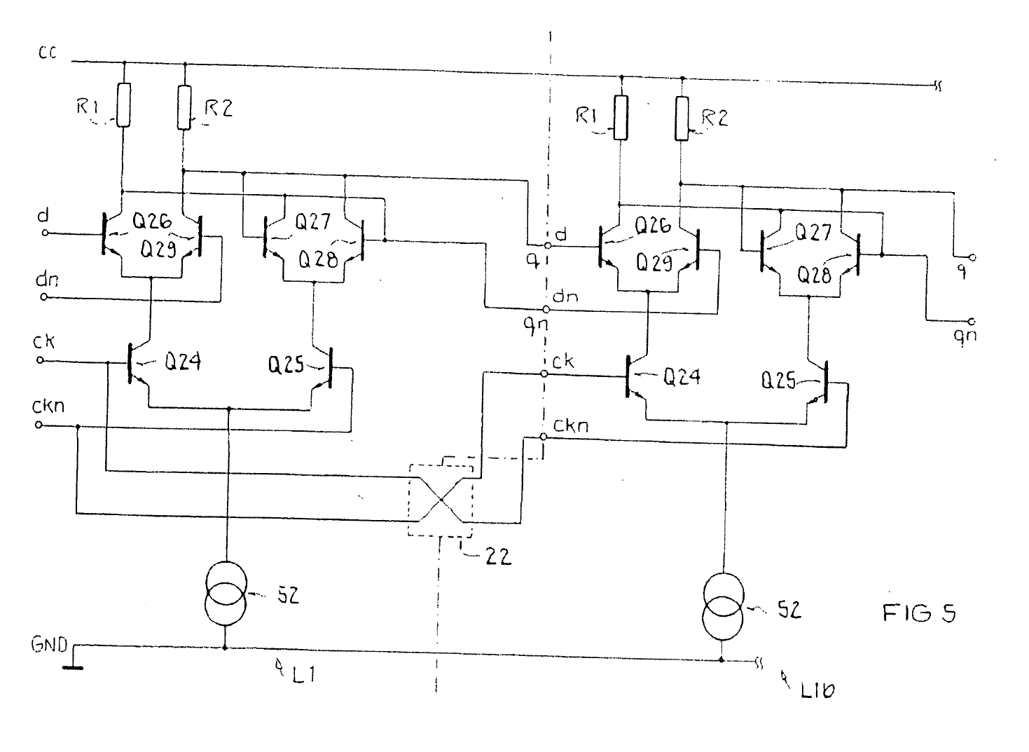

In the following, a preferred embodiment of a latch, or rather a flip-flop constructed of two latches, is explained with reference to FIGS. 4 and 5. Specifically, FIG. 4 shows a latch 48 constructed in bipolar technology. The latch 48 has a cascaded differential amplifier 50 having a constant current source 52, a first differential stage including transistors Q24, Q25, a second differential stage including transistors Q26, Q29, a third differential stage comprised of transistors Q27 and Q28, as well as a first resistance R1 and a second resistance R2, and is connected between a supply voltage connection VCC and a reference voltage connection gnd.

First current connections 54, 56 of the transistors Q26 and Q27 are connected to one another and form outputs q, qn of the latch 48. In addition, they are connected to a gate terminal 58 of the transistor Q28, and connected through the first resistance R1 to VCC.

First current connections 60, 62 of the transistors Q28 and Q29 are connected to one another and to a gate terminal 68 of the transistor Q27, and are also connected through the second resistance R2 to VCC.

Second current connections 70, 72 of the transistors Q26, Q29 are connected to one another and to a first current connection 74 of the transistor Q24. In similar fashion, second current connections 76, 78 of the transistors Q27, Q28 are connected to one another and to a first current connection 80 of the transistor Q25. Second current connections 82, 84 of the transistors Q24, Q25 are jointly connected to the constant current source 52, which is otherwise connected to gnd.

In the diagram in FIG. 4, the first current connections 54, 62, 56, 60, 74, 80 are each collector terminals, and the second current connections 70, 72, 76, 78, 82, 84 are each emitter terminals of npn bipolar transistors Q24, . . . , Q29. It is a matter of course, however, that latches 48 can also be implemented with pnp transistors if all the polarities are reversed.

As a whole, the subject of FIG. 4 represents a latch 48 in ECL technology (ECL=emitter coupled logic). ECL technology works with differential signals whose levels differ in an order of magnitude of a few hundred mV. In the explanation that follows, a high ECL level is also considered a logic one, and a low ECL level is considered a logic zero.

By means of clock signal connections ck, ckn, the first differential stage is modulated differentially with a binary clock signal. Input signal terminals d, dn serve to differentially modulate the second differential stage.

As a function of the values Wck, Wckn (CLK in the single-ended representation of FIG. 1) of the clock signal at the connections ck, ckn, and of values of an input signal Wd, Wdn (signal IN in FIG. 1), the values Wq, Wqn are produced at the outputs q, qn in accordance with the table below:

| Wd, Wdn; Wck, Wckn | q, qn |
|---|---|
| 1, 0; 1, 0 | 1, 0 |
| 1, 0; 0, 1 | previous values are maintained until |
| | Wck = 1 |
| 0, 1; 1, 0 | 0, 1 |
| 0, 1; 0, 1 | previous values are maintained until |
| | Wck = 1 |

The values in the first row of the table result from the following conditions: Wd=1 switches on the transistor Q26, while Wdn=0 inhibits the transistor Q29. Wck=1 switches on the transistor Q24, while Wckn=0 inhibits the transistor Q25. As a consequence, there results a current from VCC through R1, Q26 and Q24 to the constant current source 52, producing a voltage drop across R1. The voltage drop across R1 reduces the voltage at the first current connection 54 of Q26, and thus at the output qn, to VCC-R1*I, which by definition should correspond to a logic zero here. In contrast, no current flows through R2, so consequently there is also no voltage drop through R2. Then a logic one occurs at the output q. The values in row 3 of the table are produced in analogous fashion.

The values in the second row of the table result from the following: Wck=0 inhibits Q24, and no current flows through the first differential stage Q26, Q29. If q=0 was the case before this, then Q28 is switched on, so that q=0 remains in effect. If it was initially the case that q=1, then Q27 is switched on and, in like manner, q remains at the value 1. Row 4 of the table is produced similarly.

FIG. 5 shows a master/slave flip-flop composed of two latches L1, L1b and an inverter 22. As is evident from a comparison with FIG. 4, both the master L1 and the slave L1b, when considered each in its own right, represent a latch 48 as shown in FIG. 4. Outputs q, qn of the master L1 are connected to inputs d, dn of the slave L1b. The slave L1b is controlled by a clock signal that corresponds to the inverted clock signal CLK for the master L1. A suitable inverter 22 can be implemented by crossing the lines. Incidentally, this also applies to the inverters 24 and 26 from FIG. 1.

Following is a brief description of how an input signal Wd, Wdn=0, 1 propagates from inputs d, dn of the master L1 to the outputs q, qn of the slave L1b.

Starting from an undefined state with no input signal, it is assumed that the input signal Wd, Wdn=0, 1 and the clock signal Wck, Wckn=1, 0. This corresponds to row 3 of the table reproduced above. The values 0, 1 thus appear at the output of the master L1, and hence at the input of the slave L1b. Since the slave L1b receives the inverted clock signal 0, 1, its state then results as an initially undefined value that depends on the previous history, according to row 4 of the table. In other words, the slave L1 is blocked or disabled (i.e., the old value is retained).

For the same input signal 0, 1 let the clock signal for L1 then go to 0, 1. Then the master is disabled, in accordance with row 4 of the table, and in accordance with its previous history supplies the signal 0, 1 at its output. The slave L1b is re-enabled by the inverted clock signal 0, 1, reads in the input signal 0, 1, and provides it at its output. The master L1 is disabled in the process.

In sum, the input signal 0, 1 is read into the master L1 at the rising edge of the clock signal, and appears with a delay at the output of the slave L1b upon the next falling edge in the clock signal. If a switch of the input signal from 0, 1 to 1, 0 occurs at the input of L1 during the second clock period when the clock signal is at a high level 1 (clock signal=1, 0), then this input signal is read into the master L1 when the slave L1b is disabled, and is provided at the output of L1b when the next falling edge occurs with the slave L1b disabled and the master L1 enabled.

In other words: the pair of flip-flops L1 and L1b form, together with the inverter 22, a master/slave flip-flop. L1 and L1b are disabled in a manner complementary to one another by the clock signal Wck, Wckn. During a period when Wck is equal to 1, information is read into the master L1. The output state of L1b remains unchanged at this point, since L1b, as the slave, is blocked during this time.

When Wck goes to zero, the master L1 is disabled, and the state that had prevailed immediately prior to the falling flank is thus preserved. In this case, this is the state 0, 1 of the data signal Wd, Wdn. At the same time, the slave L1b is enabled, and consequently the state of the master L1, which is to say the state 1, is transmitted to the output of L1b. Data transmission thus takes place at the negative clock edge.

If a zero is present at the input of the master L1, it is read into the master L1 at clock Wck=1. At clock Wck=0, the zero that has been read in is forwarded to the output of the slave L1b.

FIG. 6 illustrates, in a qualitative way, the advantages of this embodiment of the individual flip-flops in ECL technology as compared to standard CMOS flip-flops, by plotting the current consumption of each over the frequency of the clock signal. The linearly rising curve 86 is that of the CMOS flip-flop, while the constant curve 88 reflects the current demand of the ECL flip-flop. As can be seen, above a cutoff frequency the current demand of the ECL flip-flop is smaller than the current demand of the standard CMOS flip-flop.

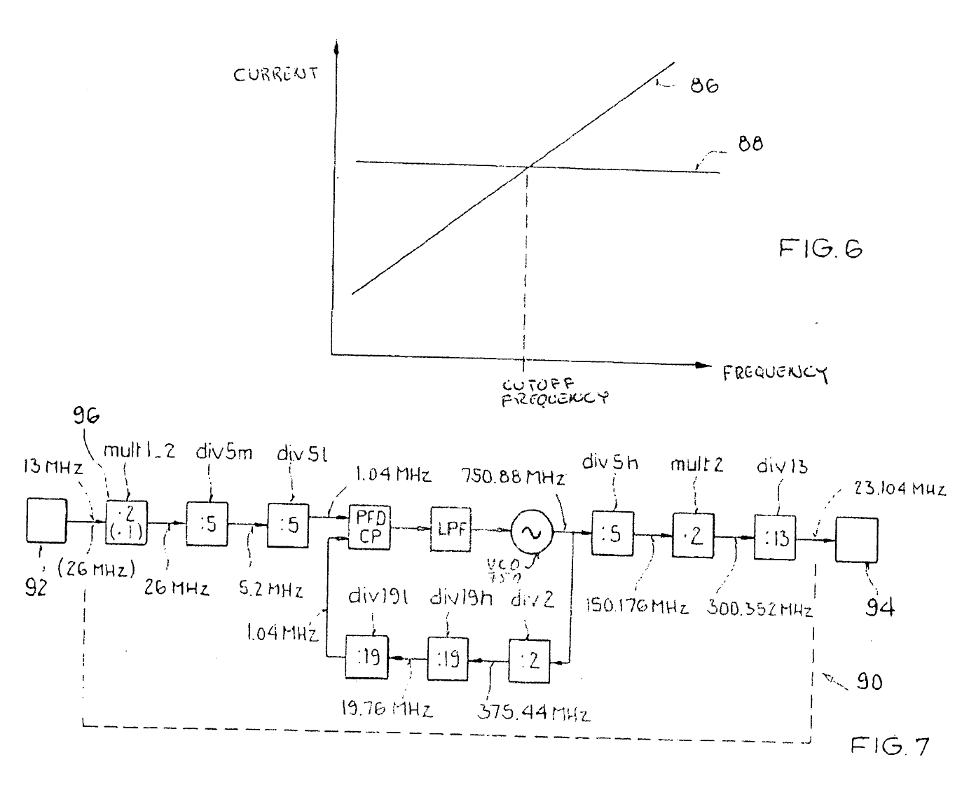

An application of embodiments of the invention, in which all the aforementioned advantages are attained, is presented with reference to FIG. 7 here. A frequency conversion circuit 90 is connected between a block 92, which represents the functions of a mobile communication device, and a block 94, which represents a GPS application that is integrated in the mobile communication device. The following explanation assumes that an internal reference frequency of 13 MHz or 26 MHz is already provided in block 92 for the functions of the mobile communication device. Other frequencies are required for the processing of GPS signals in block 94. Some examples of conventional GPS standard frequencies are 10.949297 MHz, 16.3676 MHz, 16.368 MHz, 21.73875 MHz, 23.104 MHz, 24.5535 MHz, and 27.456 MHz. In principal, any of these GPS standard frequencies can be provided through a separate quartz crystal or quartz-stabilized oscillator (for example, “TCXO”=temperature compensated crystal oscillator). However, quartz crystals are relatively expensive. In devices that already have another quartz crystal for other frequencies (here 13 MHz or 26 MHz), a GPS standard frequency can be produced in a power-saving and space-saving manner from the reference frequency present in block 92 with the aid of the frequency conversion circuit 90. For example, the frequency conversion circuit 90 shown in FIG. 7 produces the GPS standard frequency of 23.104 MHz from a frequency of 13 MHz or 26 MHz with the aid of multiplication and division by natural numbers.

The required divisions of high frequencies can be implemented through circuit technology by means of the inventive divider circuit. The required natural numbers can be determined by expanding the quotient of the existing reference frequency (here 13 MHz or 26 MHz) and the desired GPS frequency (here 23.104 MHz) to natural numbers in the numerator and denominator and subsequent decomposition of the numerator and denominator into prime factors. Thus, for example, the desired frequency of 23.104 MHz results from multiplying a frequency of 26 MHz by the prime factors 2, 2, 19, 19 and dividing by the prime factors 5, 5, 5, 13. The frequency conversion circuit 90 from FIG. 7 carries out these divisions and multiplications with the additional use of a frequency-stabilized phase-locked loop that includes a voltage-controlled oscillator VCO 750 designed for 750 MHz, a (1:2) divider div2, a (1:19) divider div19h, another (1:19) divider div19l, a phase/frequency comparator PFD with charge pump CP and a loop filter LPF. Connected ahead of the phase-locked loop is a first (1:5) divider div5m and a second (1:5) divider div5l, which successively divide the existing frequency of 26 MHz down to 5.2 MHz and 1.04 MHz. If the block 92 should provide an internal reference frequency of 13 MHz instead of 26 MHz, this frequency is multiplied by a factor of 2 in the block mult1_2, so that the frequency present at the input of the first (1:5) divider div5m is 26 MHz in any case. In order to select the factors 2 or 1 as a function of the internal reference frequencies of either 13 MHz or 26 MHz present in the block 92, the block mult1_2 has an input 96. Selection of the multiplication factor takes place, for example, in the application of the frequency conversion circuit 90 in an existing mobile telephone. The frequency of 1.04 MHz that can be obtained after the second 1:5 divider div5l serves as reference frequency for the phase-locked loop, which regulates the frequency of the VCO 750 in accordance with the dividers div2, div19h and div19l used in the loop to 722 times 1.04 MHz, which is to say to 750.88 MHz. The following factors should be considered when choosing the frequency of the VCO 750 and the reference frequency of the phase-locked loop: On the one hand, the precision and stability of the frequency conversion increases with increasing oscillator frequency and increasing spacing between the oscillator frequency and the reference frequency. On the other hand, the energy loss in the VCO also increases with increasing frequency, which is critical for mobile applications, in particular. An increase in the spacing between the oscillator frequency and the reference frequency through further reduction in the reference frequency has the disadvantage that the space required by the phase-locked loop increases, because, e.g., the size of the tuned circuit inductor in the VCO is inversely proportional to its frequency. The-figures cited represent a compromise in this regard. The VCO frequency of 750.88 MHz regulated by the phase-locked loop is divided down to the desired GPS standard frequency of 23.104 by a subsequent chain including a third (1:5) divider div5h, a frequency doubler mult2, and a (1:13) divider div13. In order to attain the aforementioned advantages of smaller space requirements in conjunction with minimized current consumption, the blocks mult1_2, div2, div19h, div5h, mult2 and div13 are preferably implemented in bipolar technology, and the blocks div5m, div5l, and div19l are implemented in CMOS technology. A circuit of the type shown in FIG. 7, which is to say a chain with frequency dividers that are implemented in either CMOS technology or bipolar technology as a function of the size of the specific frequency to be divided, can also be used without the start circuit introduced here in order to achieve minimized power consumption.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A frequency divider circuit comprising:
a chain of flip-flops that are connected by a feedback path to a feedback shift register; and
a start circuit that produces a defined initial state of the shift register when the frequency divider circuit is switched on,
wherein the start circuit blocks the feedback path for a predetermined length of time following a power up of the frequency divider circuit.

2. The frequency divider circuit according to claim 1, wherein the predetermined length of time is greater than or equal to a predetermined number of periods of a clock signal that is applied synchronously to each flip-flop of the shift register.

3. The frequency divider circuit according to claim 2, wherein the start circuit has a pair of complementary MOS transistors with their gate terminals connected to one another, and also has an RC element, wherein conductivity paths of the MOS transistors are connected through an ohmic resistance of the RC element and are connected in series between a supply voltage and a reference voltage, and wherein a capacitor of the RC element is connected in parallel to a conductivity path of one of the MOS transistors.

4. The frequency divider circuit according to claim 1, wherein the flip-flops have emitter-coupled bipolar transistors as circuit elements.

5. The frequency divider circuit according to claim 1, wherein the feedback path has a first feedback branch, a second feedback branch, and an AND gate, wherein the AND gate connects the first feedback branch and the second feedback branch to a data input of a first flip-flop of the shift register, and wherein the first feedback branch is supplied by a next-to-last flip-flop of the shift register and the second feedback branch is supplied by a last flip-flop of the shift register.

6. The frequency divider circuit according to claim 5, wherein outputs of the last and next-to-last flip-flops of the shift register are connected through an OR gate, and wherein an output of the OR gate is an output of the frequency divider circuit.

7. The frequency divider circuit according to claim 1, wherein the frequency divider circuit divides a clock signal frequency that is greater than 200 MHz.

8. The frequency divider circuit according to claim 1, wherein the frequency divider circuit generates a GPS standard frequency from an internal reference frequency of a communication device.

9. The frequency divider circuit according to claim 8, wherein the GPS standard frequency is generated by a chain of frequency multipliers and frequency dividers and a phase-locked loop.

10. The frequency divider circuit according to claim 9, wherein frequency dividers of the chain that divide a frequency that is greater than a cutoff frequency are implemented in bipolar technology, while frequency dividers of the chain that divide a frequency that is lower than the cutoff frequency are implemented in CMOS technology.

11. The frequency divider circuit according to claim 1, wherein the frequency divider circuit divides a clock signal frequency that is greater than 400 MHz.
